(19) United States
(12) Patent Application Publication
(10) Pub. No.: US 2018/0301890 A1
(43) Pub. Date: Oct. 18, 2018

(54) DETECTION OF HIGH TEMPERATURE EVENTS

(71) Applicant: HEWLETT PACKARD ENTERPRISE DEVELOPMENT LP, Houston, TX (US)

(72) Inventors: Mohamed Amin BEMAT, Cypress, TX (US); Daniel HUMPHREY, Cypress, TX (US)

(21) Appl. No.: 15/485,597

(22) Filed: Apr. 12, 2017

(51) Int. Cl. H02H 5/04; H05K 1/18; G01K 7/00; G01K 3/00

(52) U.S. Cl. CPC H02H 5/04; H05K 1/181; H05K 2201/10151; G01K 3/005; G01K 7/00

(57) ABSTRACT

Examples include detection of high temperature events. In some examples, a high temperature event may be detected in an electronic component by running the electronic component on a printed circuit board. A continuity sensor may detect whether a trace positioned under the electronic component has broken. A broken trace may indicate a high temperature event in the electronic component. Based on the detection of the broken trace, the electronic component is disconnected.

### BACKGROUND

Printed circuit board (PCB) assemblies often contain many different types of electronic components. In some instances, these electronic components may face high temperature events. If undetected or unchecked, these high temperature events can result in a runaway power event.

### BRIEF DESCRIPTION OF THE DRAWINGS

The following detailed description references the drawings, wherein:

FIG. 1 is a side view of an example printed circuit board assembly having a first and second layer;

FIG. 2 is a top-down view of an example printed circuit board assembly including an electronic component, a trace, a continuity sensor, and a driver;

FIGS. 3A-3C are top-down views of an electronic component with example traces positioned under it;

FIG. 4 is a top-down view of an example system having a printed circuit board with an electronic component, a set of traces, and a continuity sensor;

FIG. 5 is a top-down view of an example system having a printed circuit board with an electronic component, a set of traces, a continuity sensor, and a driver; and

FIGS. 6 and 7 are flowcharts of example methods to detect a high temperature event in an electronic component.

### DETAILED DESCRIPTION

A printed circuit board assembly may mechanically support and electrically connect numerous electronic components via traces, pads, and the like. Some electronic components, like power devices, may be more likely than other electronic components to generate large amounts of heat when malfunctioning. It may be useful to quickly detect such malfunctions and disconnect power to the electronic device to prevent a runaway power event that may result in a larger shut-down.

Some systems may attempt to predict a high temperature event before it occurs. Such solutions, however, may be unnecessarily complex and/or costly. In addition, predictive systems may result in false positives or false negatives, leading to unnecessary downtime and/or undetected faults. Examples described herein may improve detection of high temperature events in a printed circuit board assembly in a low-cost manner. In some instances, such examples may be used in conjunction with predictive systems or other solutions, as appropriate.

In some examples described herein, a printed circuit board assembly may comprise a first layer that includes an electronic component, a second layer below the first layer that includes a trace positioned under the electronic component, and a continuity sensor connected to the trace to detect a high temperature event in the electronic component via a break in the trace. In some such examples, the trace may further be connected to a driver and a ground via a resistor, wherein a voltage or current is driven by the driver across the trace. Upon detection of the high temperature event, the electronic component may be disconnected.

In other examples described herein, a system may comprise an electronic component, a continuity sensor, and a printed circuit board on which the electronic component resides. The printed circuit board may have a set of traces positioned under the electronic component, wherein a trace of the set of traces breaks at a temperature threshold, and wherein the trace of the set of traces is connected to the continuity sensor to detect the break in the trace. The continuity sensor may detect a high temperature event in the electronic component via the break in the trace of the set of traces. In some such examples, a driver is connected to the trace of the set of traces, wherein a voltage or current is driven by the driver across the trace. The continuity sensor may detect the high temperature event via detection of a change in the voltage or current across the trace. A break in the trace may correspond to a change in the voltage or current across the trace.

Further examples described herein may include a method of detecting a high temperature event in an electronic component comprising running an electronic component on a printed circuit board and detecting by a continuity sensor, whether a trace positioned under the electronic component has broken. The broken trace indicates a high temperature event in the electronic component. The method also includes disconnecting the electronic component based on the detection of the broken trace.

The terminology used herein is for the purpose of describing particular examples only and is not intended to be limiting. As used herein, the singular forms “a,” “an,” and “the” are intended to include the plural forms as well, unless the context clearly indicates otherwise. A “set,” as used herein, includes one or multiple items. It will also be understood that, although the terms first, second, third, etc. may be used herein to describe various elements, these elements should not be limited by these terms, as these terms are only used to distinguish one element from another unless stated otherwise or the context indicates otherwise. As used herein, the term “includes” means includes but not limited to, the term “including” means including but not limited to. In examples described herein, a determination, action, etc., that is said to be “based on” a given condition may be based on that condition alone or based on that condition and other condition(s).

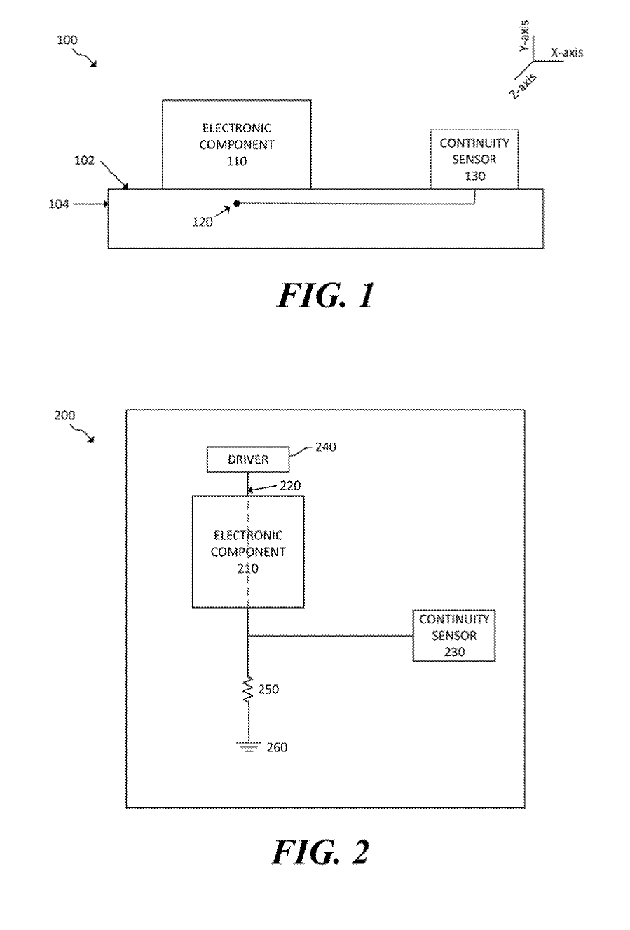

Referring now to the drawings, FIG. 1 is a side view of an example printed circuit board assembly 100 that includes an electronic component 110 and a continuity sensor 130. A printed circuit board assembly, as used herein, is a printed circuit board (PCB) with electronic components. In the examples described herein, a printed circuit board refers to a substrate that mechanically supports electronic components and includes electrical traces, tracks, pads, or other conductive substances or elements to electrically connect the electronic components. The printed circuit board may be rigid or flexible, may be a card, panel, or sheet, and may be made of any material suitable for the functionality described below.

A first layer 102 of printed circuit board assembly 100 may include electronic component 110. The first layer, as used herein, refers to a surface portion of a printed circuit board assembly where electronic components may reside. Electronic component 110 may be any of a number of devices. In some examples, electronic component 110 is a device that may generate heat, such as a power device, a power transistor, a diode, or the like. In some examples, the electrical components may be surface-mounted to or embedded in the printed circuit board. In other examples, electrical components may have leads that are inserted via through-holes in the printed circuit board.

A second layer 104 below first layer 102 includes a trace 120 positioned under electronic component 110. The second layer, as used herein, refers to a portion of the printed circuit board assembly under the first layer. In some examples, second layer 104 may include the portion of printed circuit board assembly 100 directly under electronic component 110. Trace 120 may be in second layer 104 and may be positioned directly under electronic component 110. A trace, as used herein, may refer to a thin conductive track. In some examples, a trace may be made of copper or any other suitably conductive material. The proximity of trace 120 to electronic component 110 and its thickness are such that a high temperature event in electronic component 110 causes trace 120 to physically break. For instance, trace 120 may break when exposed to a certain temperature threshold.

Trace 120 may pass under electronic component 110 in the direction of the z-axis, depicted in FIG. 1. In some examples, trace 120 may be positioned under electronic component 110 based (at least in part) on a location of heat dissipation by electronic component 110. As shown in FIG. 1, trace 120 may be connected to a continuity sensor 130. Continuity sensor 130 detects a high temperature event in electronic component 110 via a break in trace 120. A continuity sensor, as used herein, is any component capable of detecting a break in a trace. For instance, continuity sensor 130 may monitor a voltage or current across trace 120. Certain changes detected in the voltage or current across trace 120 may correspond to a break in trace 120. In other examples, continuity sensor 130 may detect other changes in trace 120 that correspond to a break.

Continuity sensor 130 may be located on first layer 102 and, in some examples, may be located far enough from electronic component 110 that it would not be affected by the high temperature event. In some examples, when continuity sensor 130 detects a high temperature event, electronic component 110 may be disconnected from power to shut down the component and contain the event. Continuity sensor 130 may alert another component or management application that shuts down or disconnects power to electronic component 110.

FIG. 2 depicts a top-down view of an example printed circuit board assembly 200. As shown, printed circuit board assembly comprises an electronic component 210 with a trace 220 that runs under the electronic component. Trace 220 is further connected to a continuity sensor 230 and a driver 240 that drives a voltage or current signal across trace 220. Driver 240 may be a voltage driver or a current driver, as appropriate. In some examples, as shown in FIG. 2, trace 220 may be connected directly to driver 240. Trace 220 may also be connected to a ground 260 via a resistor 250 and to continuity sensor 230 to detect any changes in voltage or current across trace 220.

In one example, driver 240 may be a voltage driver that drives a “high” voltage signal onto trace 220 and continuity sensor 230 may detect the “high” voltage signal when electronic component 210 is functioning normally and trace 220 is intact. If, however, electronic component 210 experiences a high temperature event that breaks trace 220, trace 220 may be pulled to ground and continuity sensor 230 may detect a “low” voltage signal, indicating to it that trace 220 is broken. In other examples, driver 240 may be a current driver and drive a current across trace 220. When trace 220 is broken, continuity sensor 230 may detect a drop in the current, indicating to it that trace 220 is broken.

Though trace 220 is shown directly connected to driver 240 and continuity sensor 230, trace 220 may also, in some examples, be connected via other components that do not affect the functionality of driver 240 and continuity sensor 230, as described. Likewise, though trace 220 is shown connected to ground 260 via resistor 250, trace 220 may be connected to ground 260 via other components that do not affect the functionality of trace 220 and continuity sensor 230, as described.

FIG. 2 depicts an example in which trace 220 passes once under the center of electronic component 210. In other examples, trace 220 may be positioned such that it passes under a portion of electronic component 210 that dissipates heat or has higher thermal volatility. In yet other examples, trace 220 may be a set of traces or a single trace that snakes back and forth under electronic component 210.

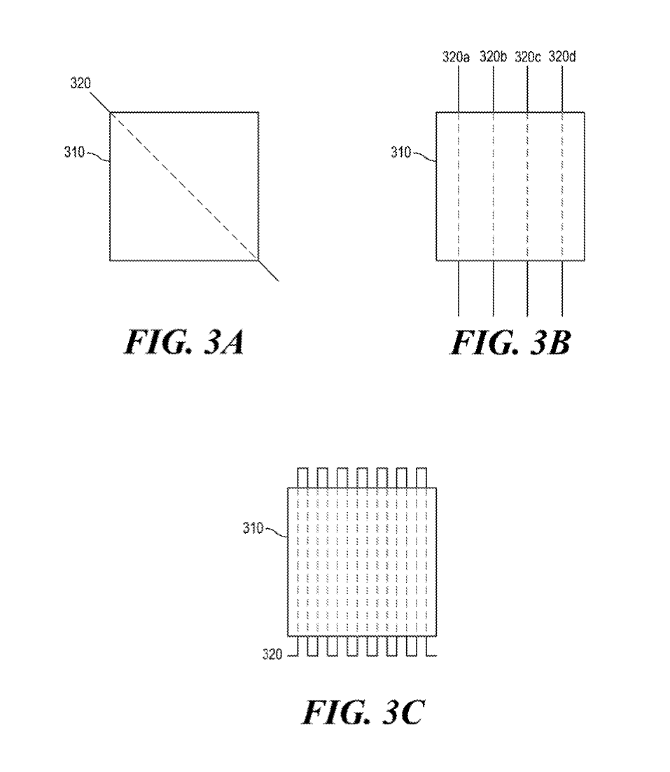

FIGS. 3A-3C depict further examples of trace positioning and layout. FIG. 3A depicts an electronic component 310 having a trace 320 that is positioned in a diagonal direction under electronic component 310. FIG. 3B depicts a set of traces 320a, 320b, 320c, and 320d positioned in a transverse direction under electronic component 310. Although four traces are depicted, more or fewer traces may be appropriate. FIG. 3C further depicts a trace 310 that snakes under the entirety of electronic component 310. In other examples, trace 310 may snake under a portion of electronic component 310. Yet other example configurations and trace layouts may be used, as appropriate.

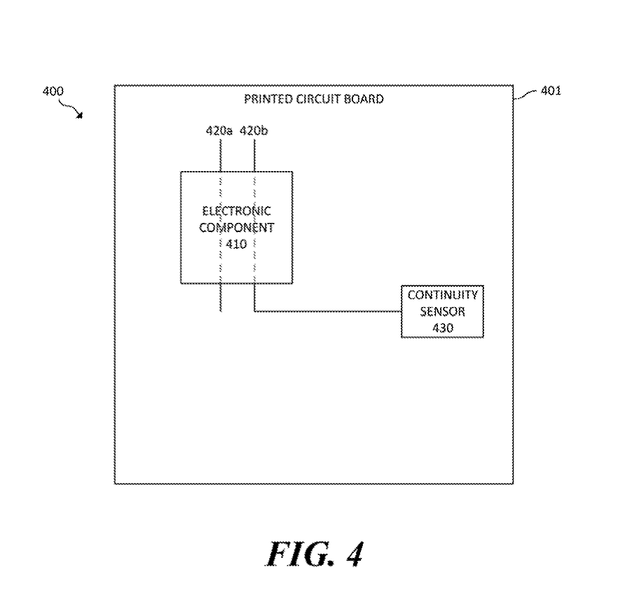

Turning now to FIG. 4, a system 400 may include a printed circuit board 401, an electronic component 410, and a continuity sensor 430. As shown, electronic component 410 may reside on printed circuit board 401. A set of traces 420a and 420b may be positioned under electronic component 410. Although the set of traces is shown as being two traces, more or fewer traces may be used, as appropriate. Moreover, a location of the set of traces under electronic component 410 may be based on a location of heat dissipation by electronic component 410. In other examples, traces may be snaked, spaced equidistantly (as shown), spaced sporadically, or spaced via any other configuration under the electronic component to detect a high temperature event.

In some examples (not shown in FIG. 4), electronic component 410 may be located at a first layer of printed circuit board 401 and the set of traces 420a and 420b may be located at a second layer of printed circuit board 401. The proximity of each trace of the set of traces to electronic component 410 and the thickness of each trace are such that a high temperature event in electronic component 410 causes a trace of the set of traces to physically break. For instance, trace 420a and/or trace 420b may break when exposed to a certain temperature threshold.

As depicted in FIG. 4, a trace of the set of traces, for instance trace 420b, may be connected to continuity sensor 430. Continuity sensor 430 detects a high temperature event in electronic component 410 via a break in trace 420b. For instance, continuity sensor 430 may monitor a voltage or current across trace 420b. Certain changes detected in the voltage or current across trace 420b may correspond to a break in trace 420b.

Continuity sensor 430 may be located far enough from electronic component 410 that it would not be affected by any high temperature event. In some examples, when continuity sensor 430 detects a high temperature event, electronic component 410 may be disconnected from power to shut down the component and contain the event. Continuity sensor 430 may alert another component or management application that shuts down or disconnects power to electronic component 410.

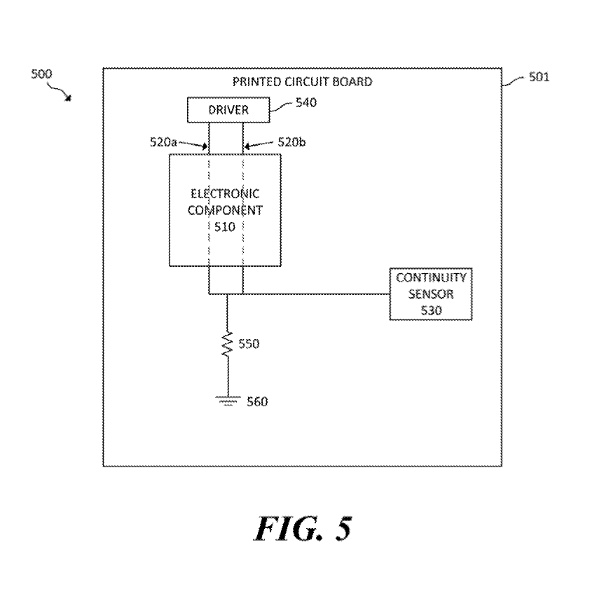

FIG. 5 depicts a top-down view of an example system 500 that includes a printed circuit board 501, an electronic component 510, a continuity sensor 530, and a driver 540. Electronic component 510 may reside on printed circuit board 501 and a set of traces 520a and 520b may be positioned under electronic component 510. Although the set of traces is shown as being two traces, more or fewer traces may be used, as appropriate. For instance, a location of the set of traces under electronic component 510 may be based on a location of heat dissipation by electronic component 510.

Each trace 520a and 520b of the set of traces may be connected to continuity sensor 530 to detect a high temperature event in electronic component 510 via a break in the trace. Each trace 520a and 520b of the set of traces may also be connected to a driver 540, as shown in FIG. 5. Driver 540 may be a voltage driver or a current driver, as appropriate, and may drive a voltage or current signal across the traces. In some examples (not shown), driver 540 may be connected to fewer than all the traces of the set of traces. For instance, in some examples, separate drivers may be connected to separate traces. In yet other examples, different traces may connect to other components.

Each trace 520a and 520b of the set of traces may also be connected to a ground 560 via a resistor 550. In some examples, each trace may be connected to ground via separate resistors or other components. In other examples (not shown) resistor 550 may be connected to fewer than all the traces of the set of traces.

In one example, driver 540 may be a voltage driver that drives a “high” voltage signal onto traces 520a and 520b and continuity sensor 530 may detect the “high” voltage signal when electronic component 510 is functioning normally and both traces 520a and 520b are intact. If, however, electronic component 510 experiences a high temperature event that breaks either or both of traces 520a or 520b, the broken trace may be pulled to ground and continuity sensor 530 may detect a “low” voltage signal. In yet other examples, driver 540 may drive a current across traces 520a and 520b. When a trace is broken, continuity sensor 530 may detect a drop in the current, indicating that a trace is broken and that electronic component 510 is experiencing a high temperature event.

Though traces 520a and 520b are shown directly connected to driver 540 and continuity sensor 530, traces 520a and 520b may also, in some examples, be connected via other components that do not affect the functionality of driver 540 and continuity sensor 530, as described. Likewise, though traces 520a and 520b are shown connected to ground 560 via resistor 550, traces 520a and 520b may be connected to ground 560 via other components that do not affect the functionality of traces 520a and 520b and continuity sensor 530, as described.

Continuity sensor 530 may be located far enough from electronic component 510 that it would not be affected by any high temperature event. In some examples, when continuity sensor 530 detects a high temperature event, electronic component 510 may be disconnected from power to shut down the component and contain the event. Continuity sensor 530 may alert another component or management application that shuts down or disconnects power to electronic component 510.

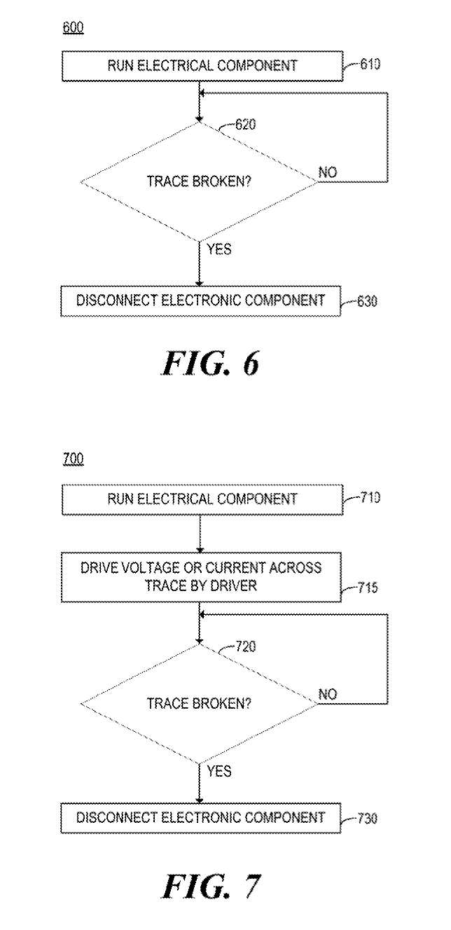

FIG. 6 is a flowchart of an example method 600 for detecting a high temperature event in an electronic component. Although method 600 is described below with reference to system 400 and printed circuit board 401 of FIG. 4, method 600 can also apply to other examples (e.g., printed circuit board assembly 100 of FIG. 1). Additionally, implementation of method 600 is not limited to such examples.

At 610, electronic component 410 of printed circuit board 401 may be run such that it is powered up and functioning. A trace (e.g., trace 420b) may be positioned under electronic component 410. In some examples, electronic component 410 may be located on a first layer of printed circuit board 401 and trace 420 may be located on a second layer of printed circuit board 401.

At 620, continuity sensor 430 may detect whether a trace (e.g., trace 420b) positioned under electronic component 410 has broken. A broken trace indicates a high temperature event in electronic component 410. In some examples, a change in a voltage or current across a trace may signal to continuity sensor 430 that the trace has broken. If continuity sensor 430 does not detect a broken trace, method 600 proceeds again to 620. If continuity sensor 430 does detect a broken trace, method 600 proceeds to 630. At 630, electronic device 410 may be disconnected based (at least in part) on the detection of the broken trace by continuity sensor 430. In some examples, continuity sensor 430 may trigger the disconnection of electronic device 410 via an alert or message to another component or management application.

Although the flowchart of FIG. 6 shows a specific order of performance of certain functionalities, method 600 is not limited to that order. For example, the functionalities shown in succession in the flowchart may be performed in a different order, may be executed concurrently or with partial concurrence, or a combination thereof. In some examples, functionalities described herein in relation to FIG. 6 may be provided in combination with functionalities described herein in relation to any of FIGS. 1-5.

FIG. 7 is a flowchart of an example method 700 for detecting a high temperature event in an electronic component. Although method 700 is described below with reference to system 500 and printed circuit board 501 of FIG. 5, method 700 can also apply to other examples (e.g., printed circuit board assembly 200 of FIG. 2). Additionally, implementation of method 700 is not limited to such examples.

At 710, electronic component 510 of printed circuit board 501 may be run such that it is powered up and functioning. A trace (e.g., trace 520a or 520b) may be positioned under electronic component 510. In some examples, electronic component 510 may be located on a first layer of printed circuit board 501 and traces 520a and 520b may be located on a second layer of printed circuit board 501.

At 715, a driver 540 may drive a voltage or current across a trace (e.g., trace 520a or 520b) such that a change in the voltage or current across the trace may correspond to a break in the trace. At 720, continuity sensor 530 may detect whether a trace (e.g., trace 520a or 520b) positioned under electronic component 510 has broken. A broken trace indicates a high temperature event in electronic component 510. If continuity sensor 530 does not detect a broken trace, method 700 proceeds again to 720. If continuity sensor 530 does detect a broken trace, method 700 proceeds to 730. At 730, electronic device 510 may be disconnected based (at least in part) on the detection of the broken trace by continuity sensor 530. In some examples, continuity sensor 530 may trigger the disconnection of electronic device 510 via an alert or message to another component or management application.

Although the flowchart of FIG. 7 shows a specific order of performance of certain functionalities, method 700 is not limited to that order. For example, the functionalities shown in succession in the flowchart may be performed in a different order, may be executed concurrently or with partial concurrence, or a combination thereof. In some examples, functionalities described herein in relation to FIG. 7 may be provided in combination with functionalities described herein in relation to any of FIGS. 1-6.

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art.

What is claimed is:

1. A printed circuit board assembly comprising:
a first layer that includes an electronic component;
a second layer below the first layer that includes a trace positioned under the electronic component; and
a continuity sensor connected to the trace to detect a high temperature event in the electronic component via a break in the trace.

2. The printed circuit board assembly of claim 1, wherein the trace breaks at a temperature threshold.

3. The printed circuit board assembly of claim 1, wherein the electronic component is a power device.

4. The printed circuit board assembly of claim 1, further comprising:
a driver connected to the trace, wherein a voltage or current is driven by the driver across the trace; and
a ground connected to the trace via a resistor.

5. The printed circuit board assembly of claim 4, wherein the break in the trace corresponds to a change in the voltage or current across the trace.

6. The printed circuit board assembly of claim 1, wherein the electronic component is disconnected upon detection of the high temperature event.

7. The printed circuit board assembly of claim 1, wherein a location of the trace under the electronic component is based on a location of heat dissipation by the electronic component.

8. The printed circuit board assembly of claim 1, wherein the trace snakes under the electronic component.

9. A system comprising:
an electronic component;
a continuity sensor; and
a printed circuit board on which the electronic component resides, the printed circuit board having a set of traces positioned under the electronic component,
wherein a trace of the set of traces breaks at a temperature threshold,
and
wherein the trace of the set of traces is connected to the continuity sensor to detect a high temperature event in the electronic component via a break in the trace of the set of traces.

10. The system of claim 9, further comprising:
a driver connected to the trace of the set of traces, wherein a voltage or current is driven by the driver across the trace.

11. The system of claim 9, further comprising:
a ground connected to the trace of the set of traces via a resistor.

12. The system of claim 10, wherein the driver is connected to each trace of the set of traces and wherein the continuity sensor is connected to each trace of the set of traces.

13. The system of claim 10, wherein the continuity sensor detects the high temperature event via detection of a change in the voltage or current across the trace.

14. The system of claim 9, wherein the electronic component is disconnected upon detection of the high temperature event.

15. The system of claim 9, wherein the electronic component is a power device.

16. The system of claim 9, wherein a location of the set of traces under the electronic component is based on a location of heat dissipation by the electronic component.

17. A method of detecting a high temperature event in an electronic component comprising:
running the electronic component on a printed circuit board;
detecting, by a continuity sensor, whether a trace positioned under the electronic component has broken, wherein the broken trace indicates a high temperature event in the electronic component; and
disconnecting the electronic component based on the detection of the broken trace.

18. The method of claim 17 further comprising:
driving a voltage or current across the trace by a driver, wherein a change in the voltage or current across the trace corresponds to a break in the trace.

19. The method of claim 17, wherein the electronic component is a power device.

20. The method of claim 17, wherein the electronic component is located on a first layer of the printed circuit board and the trace is located on a second layer of the printed circuit board adjacent to the first layer.
